(19) United States
(12) Patent Application Publication
(10) Pub. No.: US 2023/0163045 A1
(43) Pub. Date: May 25, 2023

(54) ORGANIC SPACER FOR INTEGRATED CIRCUITS

(71) Applicant: INTEL CORPORATION, Santa Clara, CA (US)

(72) Inventors: Bin LIU, Shanghai (CN); Fen YI, Shanghai (CN)

(21) Appl. No.: 17/919,730

(22) PCT Filed: May 19, 2020
(86) PCT No.: PCT/CN2020/090999

§ 371 Date: Oct. 18, 2022

(51) Int. Cl. H01L 23/373; H01L 23/00; H01L 25/065; H01L 21/48

(52) U.S. Cl. CPC H01L 23/3737; H01L 24/32; H01L 24/33; H01L 25/0657; H01L 25/0655; H01L 21/481; H01L 2224/32225; H01L 24/48; H01L 2224/48105; H01L 2224/48145; H01L 2224/48225; H01L 24/73; H01L 2224/73265; H01L 2224/33181; H01L 2224/32145; H01L 2224/73215; H01L 2225/06562; H01L 23/49827

(57) ABSTRACT

Embodiments of the present disclosure are directed to organic spacers for integrated circuits. Among other things, the organic spacers of the embodiments of the present disclosure help provide a cost-efficient and effective solution to address issues such as coefficient of thermal expansion (CTE) mismatches, dynamic warpage, and solder joint reliability (SJR). Other embodiments may be described and claimed.

### FIELD

Embodiments of the present disclosure generally relate to the field of integrated circuits, and more particularly, to organic spacers for integrated circuits.

### BACKGROUND

Integrated circuits (ICs) are used a wide variety of applications. some IC packages may have components having a large overhang relative to other supporting components. Additionally, some IC packages may suffer from corner stress concentration due to a coefficient of thermal expansion (CTE) mismatch with substrate. These stress concentrations often cause substrate trace cracks at the corner of a die. Furthermore, some IC packages may have relatively large die sizes and an unbalanced layout, which can result in dynamic warpage and solder joint reliability (SJR) issues.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIGS. 1A-1C illustrate cross-sectional views of integrated circuits utilizing organic spacers in accordance with various embodiments.

FIGS. 2A and 2B illustrate additional cross-sectional views of integrated circuits utilizing organic spacers in accordance with various embodiments.

FIG. 3 is a flow diagram illustrating an example of a process associated with providing an organic spacer in accordance with some embodiments.

FIGS. 4A-4C are isometric diagrams illustrating aspects of the process in FIG. 3.

FIG. 5 schematically illustrates an example of a computing device including an integrated circuit in accordance with various embodiments.

### DETAILED DESCRIPTION

Embodiments of the present disclosure are directed to systems, methods, and apparatuses utilizing organic spacers in IC applications. Among other things, the organic spacers of the embodiments of the present disclosure help provide a cost-efficient and effective solution to address issues such as CTE mismatches, dynamic warpage, and SJR. In some instances, the IC comprises: a semiconductor substrate; a silicon die; and a spacer disposed between the silicon die and the semiconductor substrate, wherein the spacer comprises an organic compound, and wherein the spacer is provided to reduce a coefficient of thermal expansion (CTE) mismatch between the semiconductor substrate and silicon die.

In the following description, various aspects of the illustrative implementations will be described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings that form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), (A) or (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other.

Some previous solutions to address the issues include the use of silicon spacers to raise up an overhang component and balance the structure of an IC Some previous solutions use a large silicon spacer at the bottom of an IC package in an attempt to hold substrate stress and improve SJR. Additionally, some previous solutions involve adjusting the substrate core CTE and epoxy mold compound (EMC) CTE in an attempt to try to reduce the likelihood of broken traces.

The use of silicon spacers, however, is often exceptionally expensive to implement. Similarly, adjusting substrate/EMC CTE involves the formulation and application of special EMC and substrate materials, which is likewise often costly. Moreover, the use of large silicon spacers typically only reduce (but do not eliminate) stress concentration issues.

Embodiments of the present disclosure, by contrast, help provide a more cost-efficient and effective solution to address such issues using organic spacers. For example, organic spacers of the present disclosure have a more efficient assembly process flow and can be produced at less cost than conventional silicon spacers. Additionally, the organic spacers are able to more effectively resolve the dynamic warpage issue described above by providing a balanced silicon-to-EMC ratio.

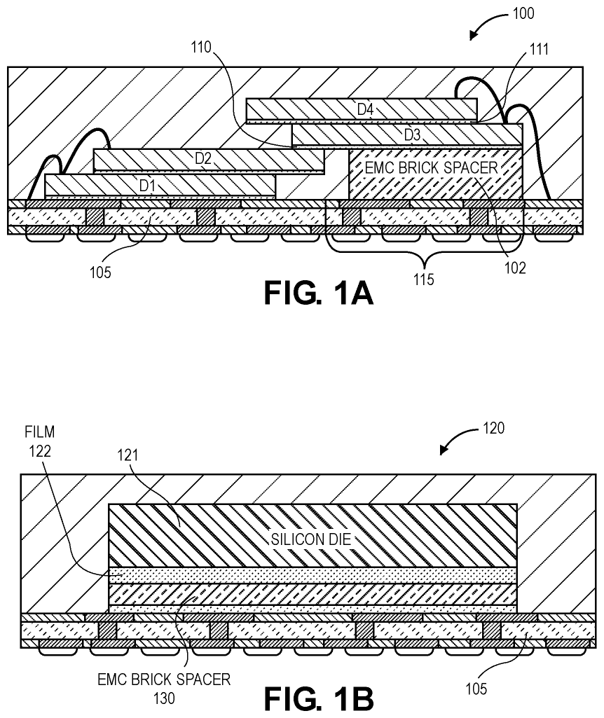

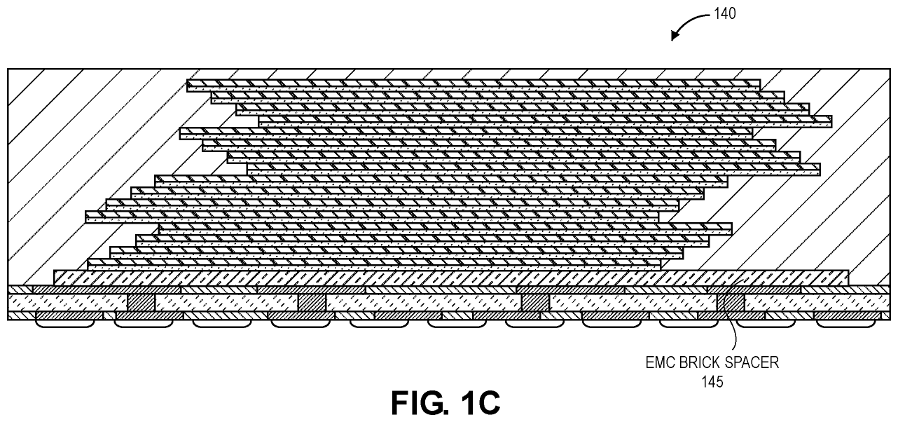

FIG. 1A illustrates a cross-sectional view of an IC utilizing an organic spacer (an EMC brick spacer in this example) in accordance with various embodiments. In this example, the organic spacer allows the IC structure to remain unchanged, while reducing or minimizing CTE mismatch between the substrate and the die. Specifically, FIG. 1A illustrates a silicon die structure 100 comprising silicon dies D1, D2, D3, and D4 disposed on a semiconductor substrate 105, wherein the D1, D2, D3 and D 4 are stacked upon each other as shown. As can be seen from FIG. 1A, the dies D3 and D4 extend out from the stacked structure 101, at least partially overhanging an area 115 of the substrate 105.

In other words, the layout structure of silicon dies D1-D4 is be provided wherein silicon die D1 is disposed in contact with the substrate 205, but free from contact with silicon die D3 and spacer 100. While silicon die D2 is disposed between silicon die D1 and silicon die D3, silicon die D3 substantially overhangs (in area 115) silicon die D2, and the spacer 102 provides support for silicon dies D3 and D4. In conventional solutions, such overhanging may result in a somewhat unbalanced state of the structure 101.

As shown in FIG. 1A, spacer 102 is disposed between silicon die D3 and the semiconductor substrate 105, wherein the spacer comprises an organic compound, and wherein the spacer is provided to reduce a coefficient of thermal expansion (CTE) mismatch between the semiconductor substrate 105 and silicon die D3. In this example, the spacer 102 comprises the organic compound EMC. However, spacers used in conjunction with the embodiments of the present disclosure may be formed from other organic compounds as well, such as an organic solder mask material. In some embodiments, an organic spacer may be formed from two or more different organic compounds.

In FIG. 1A, the layout structure 100 of silicon dies D1-D4 can be provided wherein silicon die D1 is in contact with the substrate 205, but free from contact with silicon die D3 and spacer 102. While silicon die D2 is disposed between silicon die D1 and silicon die D3, silicon die D3 substantially overhangs silicon die D2, and the spacer 102 provides support for silicon dies D3 and D4.

As shown in FIG. 1A, spacer 102 is disposed between silicon die D3 and the semiconductor substrate 105, to reduce or minimize the stress and warping issues described above, and further to provide for steadying the overhanging dies D3 and D4, thus providing for the balance of the structure 100. In embodiments, the spacer 102 comprises an organic compound, and can provide for reduction of a coefficient of thermal expansion (CTE) mismatch between the semiconductor substrate 105 and silicon die D3. In this example, the spacer 102 comprises the organic compound EMC. However, spacers used in conjunction with the embodiments of the present disclosure may be formed from other organic compounds as well, such as an organic solder mask material. In some embodiments, an organic spacer may be formed from two or more different organic compounds.

FIGS. 1B and 1C illustrate the use of organic spacers according to embodiments of the present disclosure. FIG. 1B illustrates an example of a layout structure 120 where the silicon die 121 includes a film layer 122 that is in contact with spacer 130. Similarly, silicon dies D1-D4 in FIG. 1A may likewise include film layer. In FIG. 1A, for example, silicon die D3 includes a film layer 110 that is in contact with the spacer 102. The film layer 111 on the bottom side of silicon die D4 is likewise in contact with the top side of silicon die D3. In FIG. 1B, the organic spacer 130 helps reduce CTE mismatches between silicon die 121 and substrate 105, thus helping to reduce corner stress concentration and substrate trace cracking at the corners of the silicon die 121.

FIG. 1C illustrates an example of an elongated organic spacer 145 (e.g., an EMC brick spacer) at the bottom of a silicon die structure 140. Among other things, the elongated organic spacer 145 helps structure support large die sizes in structure 140, thus helping to address issues of dynamic warpage and SJR.

In some embodiments, organic spacers may be used to help provide a solution to reduce IC package layout design sizes. Additionally, organic spacers of the present disclosure can help better utilize vertical space and horizontal space in an IC package layout with changes to the EMC-to-Silicon ratio. For example, in some instances an IC layout may lack horizontal space between the components, yet have unused space in the vertical direction.

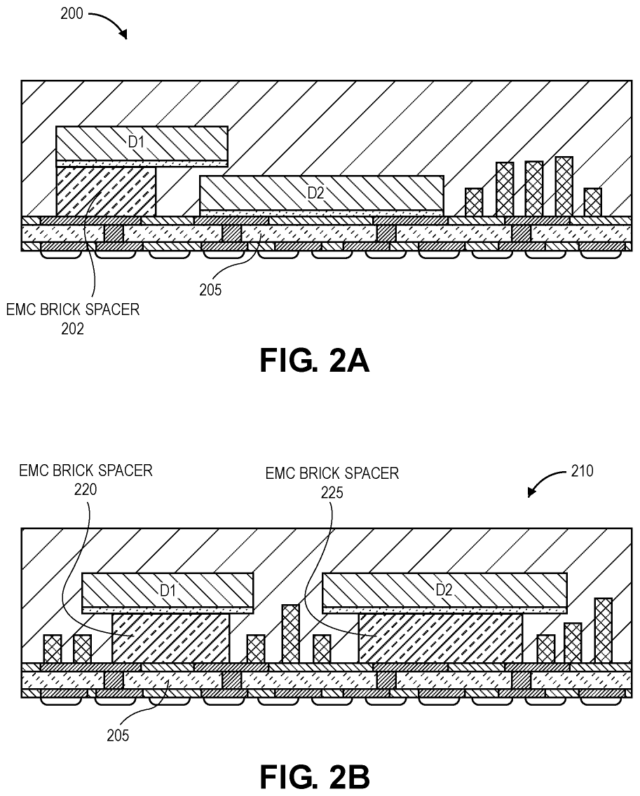

FIGS. 2A and 2B illustrate additional cross-sectional views of integrated circuits utilizing organic spacers in accordance with various embodiments. Specifically, FIG. 2A illustrates a cross-sectional view of an example of an IC that provides for increased horizontal spacing between the components according to some embodiments. As shown, the structure 200 may use an organic spacer 202 (an EMC spacer in this example) disposed between the substrate 205 and silicon die D1 to raise the level of silicon die D1 to overhang silicon die D2 and allow for increased horizontal spacing between the components.

FIG. 2B illustrates an example of another embodiment. In this example, layout structure 210 includes a first organic spacer 220 that is disposed between the substrate 205 and silicon die D1 in order to raise the vertical level of silicon die D1, while a second organic spacer 225 is adjacent to the first spacer 220 and disposed between the substrate 205 and silicon die D2 to raise the vertical level of silicon die D2. In this manner, the spacers 220 and 225 allow the vertical space of the layout structure 210 to be better utilized and allow the silicon dies D1, D2 to overlap other components, while remaining free from contact with them.

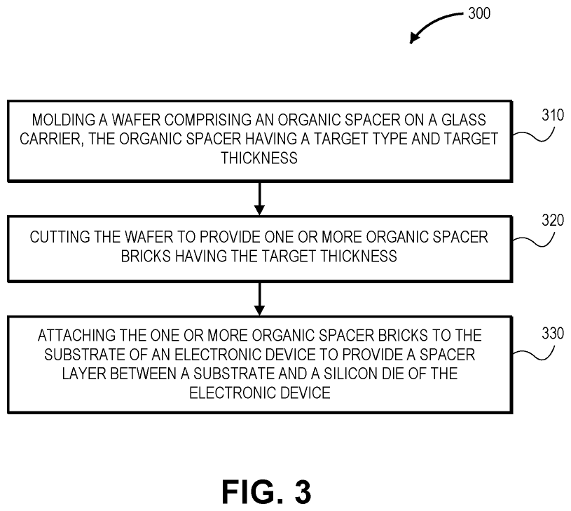

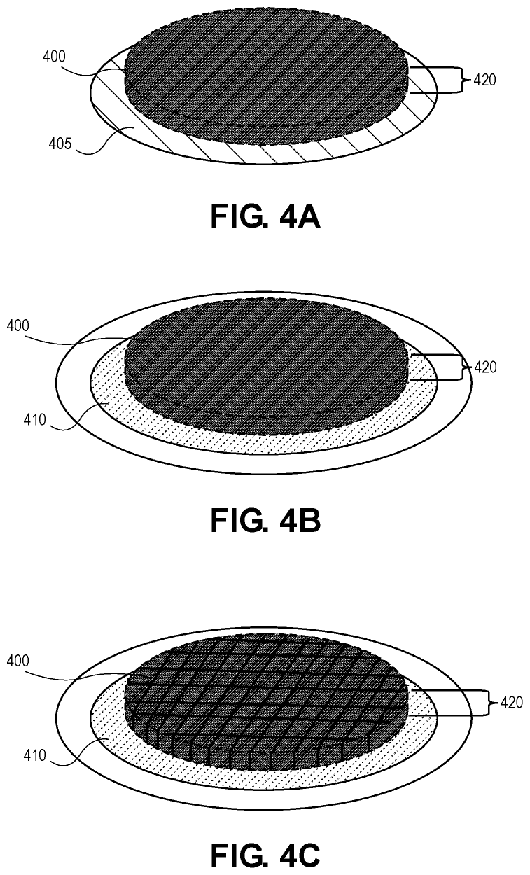

FIG. 3 is flow diagram illustrating an example of a process 300 for providing an organic spacer in accordance with various embodiments of the present disclosure. The description of the process 300 is provided with reference to the isometric diagrams illustrated in FIGS. 4A-4C.

As illustrated in FIG. 3, process 300 includes, at 310, molding a wafer comprising an organic spacer on a glass carrier, the organic spacer having a target type and a target thickness. FIG. 4A illustrates an example of this step, where wafer 400, having a target EMC type and target thickness 420, is molded on glass carrier 405. As shown in FIG. 4B, the molded wafer 400 can be separated from the glass carrier 405 and mounted on a film 410.

Process 300 further includes, at 320, cutting the wafer to provide one or more organic spacer bricks having the target thickness 420 as illustrated in FIG. 4C. The organic spacer bricks may be cut (e.g., in a grid pattern as shown in FIG. 4C) to a particular target size for an application in a particular circuit. Accordingly, the organic spacer bricks may be cut to a target size having the target thickness 420 and any suitable target length and target width. The one or more organic spacer bricks may be disposed on a substrate of an electronic device to reduce a coefficient of thermal expansion (CTE) mismatch between the substrate and a silicon die of the electronic device based on the target type.

Process 300 further includes, at 330, attaching the one or more organic spacer bricks to the substrate of the electronic device to provide a spacer layer between the substrate and the silicon die of the electronic device, wherein the silicon die is disposed or to be disposed on the substrate. The spacer bricks may be attached to the substrate of the device in a variety of configurations, examples of which are illustrated and described above in FIGS. 1A-1C and 2A-2B.

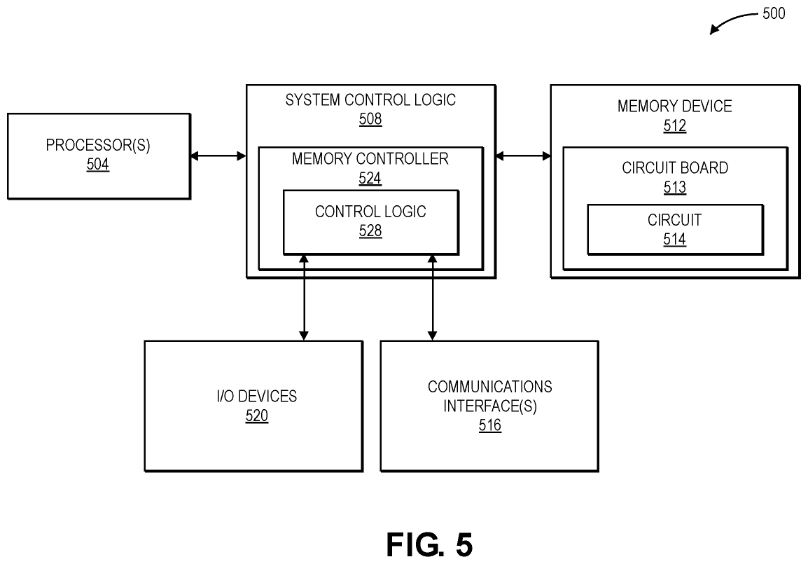

FIG. 5 schematically illustrates an example computing device that may include an integrated circuit having one or more organic spacers according to various embodiments disclosed herein. The computing device 500 includes system control logic 508 coupled to one or more processor(s) 504; a memory device 512; one or more communications interface(s) 516; and input/output (I/O) devices 520. In some embodiments, for example, an integrated circuit including one or more organic spacers (e.g., as illustrated in FIGS. 1A-1C and 2A-2B) may be included in the memory device 512, or in another of the components of system 500.

For example, the memory device 512 may include a package die 514 coupled to a circuit board 513, the package die 514 including a semiconductor substrate, a silicon die, and a spacer disposed between the silicon die and the semiconductor substrate, wherein the spacer comprises an organic compound, and wherein the spacer is provided to reduce a coefficient of thermal expansion (CTE) mismatch between the semiconductor substrate and silicon die.

The memory device 512 may be a non-volatile computer storage chip (e.g., provided on the die). In some embodiments, the memory device 512 comprises a package, such as an IC assembly having the memory device 512 disposed therein, driver circuitry (e.g., drivers), input/output connections to electrically couple the memory device 512 with other components of the computing device 500, etc. The memory device 512 may be configured to be removably or permanently coupled with the computing device 500. In embodiments, memory device 512 includes, e.g., a NAND device, e.g. 3D SLC, TLC (triple-level per cell), QLC (quad-level per cell), or SLC NAND device.

In some embodiments, memory device 512 includes any suitable persistent memory e.g., a write-in-place byte addressable non-volatile memory that benefits from embodiments, such as any memory device that scales vertically. In some embodiments, memory device 512 may include any suitable memory that stores data by changing the electrical resistance of the memory cells. In embodiments, memory 512 can include a byte-addressable write-in-place three dimensional crosspoint memory device, or other byte addressable write-in-place NVM device, such as single or multi-level Phase Change Memory (PCM) or phase change memory with a switch (PCMS), NVM devices that use chalcogenide phase change material (for example, chalcogenide glass), resistive memory including metal oxide base, oxygen vacancy base and Conductive Bridge Random Access Memory (CB-RAM), nanowire memory, ferroelectric random access memory (FeRAM, FRAM), magneto resistive random access memory (MRAM) that incorporates memristor technology, spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory.

Communications interface(s) 516 may provide an interface for computing device 1200 to communicate over one or more network(s) and/or with any other suitable device. Communications interface(s) 516 may include any suitable hardware and/or firmware. Communications interface(s) 516 for one embodiment may include, for example, a network adapter, a wireless network adapter, a telephone modem, and/or a wireless modem. For wireless communications, communications interface(s) 516 for one embodiment may use one or more antennas to communicatively couple the computing device 500 with a wireless network.

For one embodiment, at least one of the processor(s) 504 may be packaged together with logic for one or more controller(s) of system control logic 508. For one embodiment, at least one of the processor(s) 504 may be packaged together with logic for one or more controllers of system control logic 508 to form a System in Package (SiP). For one embodiment, at least one of the processor(s) 504 may be integrated on the same die with logic for one or more controller(s) of system control logic 508. For one embodiment, at least one of the processor(s) 504 may be integrated on the same die with logic for one or more controller(s) of system control logic 508 to form a System on Chip (SoC).

System control logic 508 for one embodiment may include any suitable interface controllers to provide for any suitable interface to at least one of the processor(s) 504 and/or to any suitable device or component in communication with system control logic 508. The system control logic 508 may move data into and/or out of the various components of the computing device 500.

System control logic 508 for one embodiment may include a memory controller 824 to provide an interface to the memory device 512 to control various memory access operations. The memory controller 524 may include control logic 528 that may be specifically configured to control access of the memory device 512.

In various embodiments, the I/O devices 520 may include user interfaces designed to enable user interaction with the computing device 500, peripheral component interfaces designed to enable peripheral component interaction with the computing device 500, and/or sensors designed to determine environmental conditions and/or location information related to the computing device 500. In various embodiments, the user interfaces could include, but are not limited to, a display, e.g., a liquid crystal display, a touch screen display, etc., a speaker, a microphone, one or more digital cameras to capture pictures and/or video, a flashlight (e.g., a light emitting diode flash), and a keyboard. In various embodiments, the peripheral component interfaces may include, but are not limited to, a non-volatile memory port, an audio jack, and a power supply interface. In various embodiments, the sensors may include, but are not limited to, a gyro sensor, a proximity sensor, an ambient light sensor, and a positioning unit. The positioning unit may additionally/alternatively be part of, or interact with, the communication interface(s) 516 to communicate with components of a positioning network, e.g., a global positioning system (GPS) satellite.

In various embodiments, the computing device 500 may be a mobile computing device such as, but not limited to, a laptop computing device, a tablet computing device, a netbook, a smartphone, etc.; a desktop computing device; a workstation; a server; etc. The computing device 500 may have more or fewer components, and/or different architectures. In further implementations, the computing device 500 may be any other electronic device that processes data.

### EXAMPLES

According to various embodiments, the present disclosure describes a number of examples.

Example 1 includes an apparatus comprising: a semiconductor substrate; a silicon die; and a spacer disposed between the silicon die and the semiconductor substrate, wherein the spacer comprises an organic compound, and wherein the spacer is provided to reduce a coefficient of thermal expansion (CTE) mismatch between the semiconductor substrate and silicon die.

Example 2 includes the apparatus of example 1 or some other example herein, wherein the organic compound comprises an epoxy mold compound (EMC) or an organic solder mask material.

Example 3 includes the apparatus of example 1 or some other example herein, wherein the silicon die includes a film layer, and wherein the film layer is in contact with the spacer.

Example 4 includes the apparatus of example 1 or some other example herein, wherein the silicon die is a first silicon die, and the apparatus further comprises a second silicon die in contact with the semiconductor substrate.

Example 5 includes the apparatus of example 4 or some other example herein, wherein the second silicon die is free from contact with the first silicon die or the EMC spacer.

Example 6 includes the apparatus of example 4 or some other example herein, wherein the apparatus further comprises a third silicon die disposed between first silicon die and the second silicon die.

Example 7 includes the apparatus of any of examples 4-6 or some other example herein, wherein each respective silicon die includes a respective film layer.

Example 8 includes the apparatus of example 1 or some other example herein, wherein the silicon die is a first silicon die, wherein a first side of the first silicon die is in contact with the spacer, and wherein a second side of the first silicon die is in contact with a second silicon die.

Example 9 includes the apparatus of example 8 or some other example herein, wherein the first silicon die includes a first film layer on its first side contacting the spacer, and wherein the second silicon die includes a second film layer in contact with second side of the first silicon die.

Example 10 includes the apparatus of example 1 or some other example herein, wherein the silicon die is a first silicon die and the spacer is a first spacer, and wherein the apparatus further comprises: a second silicon die; and a second spacer adjacent to the first spacer, the second spacer disposed between the substrate and the second silicon die.

Example 11 includes a method comprising: molding a wafer comprising an organic spacer on a glass carrier, the organic spacer having a target type and a target thickness; and cutting the wafer to provide one or more organic spacer bricks having the target thickness, wherein the one or more organic spacer bricks are to be disposed on a substrate of an electronic device to reduce a coefficient of thermal expansion (CTE) mismatch between the substrate and a silicon die of the electronic device based on the target type.

Example 12 includes the method of example 11 or some other example herein, further comprising attaching the one or more organic spacer bricks to the substrate of the electronic device to provide a spacer layer between the substrate and the silicon die of the electronic device, wherein the silicon die is disposed or to be disposed on the substrate.

Example 13 includes the method of example 11 or some other example herein, wherein the organic spacer has a target type that comprises an epoxy mold compound (EMC) or an organic solder mask material.

Example 14 includes the method of example 11 or some other example herein, wherein cutting the wafer includes providing the one or more spacer bricks with a target size, the target size including the target thickness, a target length, and a target width.

Example 15 includes the method of example 11 or some other example herein, wherein the silicon die is a first silicon die, and the electronic device further comprises a second silicon die in contact with the substrate.

Example 16 includes the method of example 15 or some other example herein, wherein the second silicon die is free from contact with the first silicon die or the organic spacer.

Example 17 includes a computing device comprising: a circuit board; and a package die coupled with the circuit board, the package die including: a semiconductor substrate; a silicon die; and a spacer disposed between the silicon die and the semiconductor substrate wherein the spacer comprises an organic compound, and wherein the spacer is provided to reduce a coefficient of thermal expansion (CTE) mismatch between the semiconductor substrate and silicon die.

Example 18 includes the computing device of example 17 or some other example herein, wherein the organic compound comprises an epoxy mold compound (EMC) or an organic solder mask material.

Example 19 includes the computing device of example 17 or some other example herein, wherein the silicon die includes a film layer, and wherein the film layer is in contact with the spacer.

Example 20 includes the computing device of example 17 or some other example herein, wherein the silicon die is a first silicon die, and the package die further comprises a second silicon die in contact with the semiconductor substrate.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated implementations, including what is described in the Abstract, is not intended to be exhaustive or to limit the embodiments of the present disclosure to the precise forms disclosed. While specific implementations and examples are described herein for illustrative purposes, various equivalent modifications are possible within the scope of the present disclosure, as those skilled in the relevant art will recognize.

These modifications may be made to embodiments of the present disclosure in light of the above detailed description. The terms used in the following claims should not be construed to limit various embodiments of the present disclosure to specific implementations disclosed in the specification and the claims. Rather, the scope is to be determined entirely by the following claims, which are to be construed in accordance with established doctrines of claim interpretation.

1-20. (canceled)

21. An apparatus comprising:
a semiconductor substrate;
a silicon die; and
a spacer disposed between the silicon die and the semiconductor substrate, wherein the spacer comprises an organic compound, and wherein the spacer is provided to reduce a coefficient of thermal expansion (CTE) mismatch between the semiconductor substrate and silicon die.

22. The apparatus of claim 21, wherein the organic compound comprises an epoxy mold compound (EMC) or an organic solder mask material.

23. The apparatus of claim 21, wherein the silicon die includes a film layer, and wherein the film layer is in contact with the spacer.

24. The apparatus of claim 21, wherein the silicon die is a first silicon die, and the apparatus further comprises a second silicon die in contact with the semiconductor substrate.

25. The apparatus of claim 24, wherein the second silicon die is free from contact with the first silicon die or the EMC spacer.

26. The apparatus of claim 24, wherein the apparatus further comprises a third silicon die disposed between first silicon die and the second silicon die.

27. The apparatus of claim 24, wherein each respective silicon die includes a respective film layer.

28. The apparatus of claim 21, wherein the silicon die is a first silicon die, wherein a first side of the first silicon die is in contact with the spacer, and wherein a second side of the first silicon die is in contact with a second silicon die.

29. The apparatus of claim 28, wherein the first silicon die includes a first film layer on its first side contacting the spacer, and wherein the second silicon die includes a second film layer in contact with second side of the first silicon die.

30. The apparatus of claim 21, wherein the silicon die is a first silicon die and the spacer is a first spacer, and wherein the apparatus further comprises:
a second silicon die; and
a second spacer adjacent to the first spacer, the second spacer disposed between the substrate and the second silicon die.

31. A method comprising:
molding a wafer comprising an organic spacer on a glass carrier, the organic spacer having a target type and a target thickness; and
cutting the wafer to provide one or more organic spacer bricks having the target thickness, wherein the one or more organic spacer bricks are to be disposed on a substrate of an electronic device to reduce a coefficient of thermal expansion (CTE) mismatch between the substrate and a silicon die of the electronic device based on the target type.

32. The method of claim 31, further comprising attaching the one or more organic spacer bricks to the substrate of the electronic device to provide a spacer layer between the substrate and the silicon die of the electronic device, wherein the silicon die is disposed or to be disposed on the substrate.

33. The method of claim 31, wherein the organic spacer has a target type that comprises an epoxy mold compound (EMC) or an organic solder mask material.

34. The method of claim 31, wherein cutting the wafer includes providing the one or more spacer bricks with a target size, the target size including the target thickness, a target length, and a target width.

35. The method of claim 31, wherein the silicon die is a first silicon die, and the electronic device further comprises a second silicon die in contact with the substrate.

36. The method of claim 35, wherein the second silicon die is free from contact with the first silicon die or the organic spacer.

37. A computing device comprising:
a circuit board; and
a package die coupled with the circuit board, the package die including:
a semiconductor substrate;
a silicon die; and
a spacer disposed between the silicon die and the semiconductor substrate wherein the spacer comprises an organic compound, and wherein the spacer is provided to reduce a coefficient of thermal expansion (CTE) mismatch between the semiconductor substrate and silicon die.

38. The computing device of claim 37, wherein the organic compound comprises an epoxy mold compound (EMC) or an organic solder mask material.

39. The computing device of claim 37, wherein the silicon die includes a film layer, and wherein the film layer is in contact with the spacer.

40. The computing device of claim 37, wherein the silicon die is a first silicon die, and the package die further comprises a second silicon die in contact with the semiconductor substrate.
